(19) United States
(12) Patent Application Publication
(10) Pub. No.: US 2025/0021054 A1
(43) Pub. Date: Jan. 16, 2025

(54) TIMEPIECE COMPRISING A PROTECTIVE GLASS WITH AN ANTI-FOGGING DEVICE

(71) Applicant: The Swatch Group Research and Development Ltd, Marin (CH)

(72) Inventor: Jean-Claude MARTIN, Montmollin (CH)

(73) Assignee: The Swatch Group Research and Development Ltd, Marin (CH)

(21) Appl. No.: 18/664,385

(22) Filed: May 15, 2024

(30) Foreign Application Priority Data
Jul. 10, 2023 (EP) 23184370.7

(51) Int. Cl. G04B 43/00; G04B 39/00; G04B 39/02

(52) U.S. Cl. CPC G04B 43/005; G04B 39/002; G04B 39/02

(57) ABSTRACT

A timepiece including a middle closed by a back cover and by a protective glass, the timepiece includes an anti-fogging device for the protective glass, the anti-fogging device including a layer of transparent conductive oxides provided at least on a portion of an internal surface of the protective glass; a thermal interface member, having a thermal conductivity greater than or equal to 1 W/m·K, provided in the middle and configured to: a) ensure heat exchange by contact between the conductive oxide layer and the middle, the middle and the back cover being made of a thermally conductive material, or b) ensure heat exchange by contact between the conductive oxide layer and the back cover, the back cover including at least one part made of a thermally conductive material in contact with the thermal interface member.

### TECHNICAL FIELD OF THE INVENTION

The present invention relates to a timepiece comprising a protective glass having an anti-fogging device to prevent or limit the formation of fog, or fine water droplets, on the inner surface of the protective glass.

### TECHNOLOGICAL BACKGROUND

Timepieces are worn on a daily basis in environments that vary greatly in terms of relative humidity, pressure and temperature. A timepiece structurally prevents moisture from penetrating the main body, but is subject to gaseous exchanges between the interior of the main body and the outside environment, despite being watertight.

This gas exchange, referred to as permeation, takes place through the joints, which are mainly made of polymer materials with variable, but never zero, permeation properties. In very hot and humid environments, water vapour can thus regularly penetrate a timepiece, which in itself is not a problem because it is invisible to the user as long as there is no visible fog on the inside of the protective glass.

Fogging most often occurs when the temperature to which the wearer is subjected drops, for example when swimming or entering an air-conditioned environment where the temperature is several degrees lower than previously. As the protective glass is the point of closest contact with the outside environment, fine droplets of water formed by condensation naturally adhere to the inner surface of the protective glass. The wearer notices the presence of fog on the inside of the timepiece and often mistakenly thinks that the product is no longer waterproof. This phenomenon is the source of numerous product returns, as well as of a loss of confidence among users, and thus of a deterioration to the image of the watch brand.

Hydrophilic treatments exist, which treatments consist of applying a surface-active agent to the inner surface of the protective glass to prevent fine droplets of water from adhering to the surface of the protective glass. These hydrophilic layers allow the water to spread over the entire inner surface of the protective glass and thus remain invisible to the wearer. However, these hydrophilic layers are not always compatible with good aesthetics (colouring, diffusing effect, etc).

Another method is based on the principle of absorbing the water contained in the vapour entering the timepiece. However, these solutions are limited in time and the absorption capacities are limited (in quantity). As a result, these solutions are not entirely satisfactory.

There is thus a need to improve the anti-fogging capacity of the protective glass and of timepieces fitted with such protective glass.

### SUMMARY OF THE INVENTION

To this end, the present invention offers a solution to the problems of the prior art by proposing a timepiece fitted with a protective glass comprising a transparent anti-fogging device, with an excellent anti-fogging capacity to prevent the formation of fog in various environments of use, the effectiveness of which is not limited in time and which is not limited by a maximum absorption capacity.

In this context, the invention proposes a timepiece comprising a middle in which a horological movement is housed, the middle being closed by a back cover and by a protective glass, said timepiece being characterised in that it comprises an anti-fogging device for said protective glass, said anti-fogging device comprising:
a layer of transparent conductive oxides provided on at least a portion of an inner surface of the protective glass;
a thermal interface member, having a thermal conductivity greater than or equal to 1 W/m·K, arranged in said middle and configured to:
   a) ensure heat exchange by contact between said conductive oxide layer and the middle, the middle and said back cover being made of a thermally conductive material, or
   b) ensure heat exchange by contact between said conductive oxide layer and the back cover, said back cover comprising at least one part made of a thermally conductive material in contact with said thermal interface member.

The anti-fogging device according to the invention makes it possible to obtain passive heating of the protective glass by using the thermal conduction properties of the layer of transparent conductive oxides and by bringing the latter into contact with the back cover made of thermally conductive material in order to benefit from the wearer's body heat when the timepiece is worn. Thus, the protective glass is no longer the cold spot of the timepiece.

Such an anti-fogging device is thus not limited in time and its capacity to prevent fogging is not limited.

The back cover, which is thermally conductive and in contact with the wearer's skin, allows heat exchange by “direct” conduction with the thermal interface member when the latter is in contact with the back cover, or heat exchange by “indirect” conduction with the thermal interface member, via the middle 11 made of a thermally conductive material, when the thermal interface member is in contact only with the middle.

In addition to the features mentioned in the previous paragraph, the timepiece according to the invention can have one or more of the following additional features, considered individually or in any combination technically possible:
the layer of transparent conductive oxides is composed of tin-doped indium oxide, aluminium-doped zinc oxide, zinc oxide or fluorine-doped tin dioxide;
the thermally conductive member is a thermally conductive elastomer joint formed between the middle and the protective glass;
the thermally conductive elastomer joint is made of a silicone- or fluorosilicone-based elastomer;
the thermally conductive elastomer joint seals the middle at the protective glass;
the thermal interface member is a thermally conductive pad housed in a recess in the middle;
the thermally conductive pad is composed of one or more polymers and of metal, ceramic, or carbon-based particles and/or of carbon fibres, or a mixture of these particles and/or fibres;
the thermally conductive pad is composed of an elastomer, preferably silicone, and ceramic particles;
the thermal interface member is formed by a plurality of conductive pads;
the thermal interface member is annular in shape.

According to a first alternative embodiment of the invention, the thermal interface member is a thermally conductive pad provided in the middle, the thermal interface member being in contact with the layer of transparent conductive oxides and at least part of the back cover to ensure heat exchange by conduction between the conductive oxide layer and the back cover.

In this first alternative embodiment of the invention, the timepiece can further comprise a system for positioning the thermal interface member, made at least in part from a thermally insulating material and configured to ensure thermal conduction between the back cover and the conductive oxide layer while thermally insulating the thermal interface member from the middle.

According to a second alternative embodiment of the invention, the thermal interface member is a thermally conductive pad provided in the middle, the thermal interface member being in contact with the layer of transparent conductive oxides and the middle to ensure heat exchange by conduction between the conductive oxide layer and the middle. The middle and back cover are made of a thermally conductive material to ensure heat exchange by conduction between the middle and the back cover.

In this second alternative embodiment, the middle can comprise a thermally insulating insert preventing heat exchange by conduction and then convection between the external environment and the thermal interface member, via the middle.

### BRIEF DESCRIPTION OF THE FIGURES

The aims, advantages and features of the present invention will become apparent from the detailed description below, given with reference to the following figures:

FIG. 1 diagrammatically shows a partial cross-sectional view of a first example embodiment of a timepiece comprising an anti-fogging device according to the invention;

FIG. 2 diagrammatically shows an alternative to the first example embodiment illustrated in FIG. 1;

FIG. 3 diagrammatically shows a partial cross-sectional view of a second example embodiment of a timepiece comprising an anti-fogging device according to the invention.

Common elements bear the same reference numerals in all of the drawings unless specified otherwise.

### DETAILED DESCRIPTION OF THE INVENTION

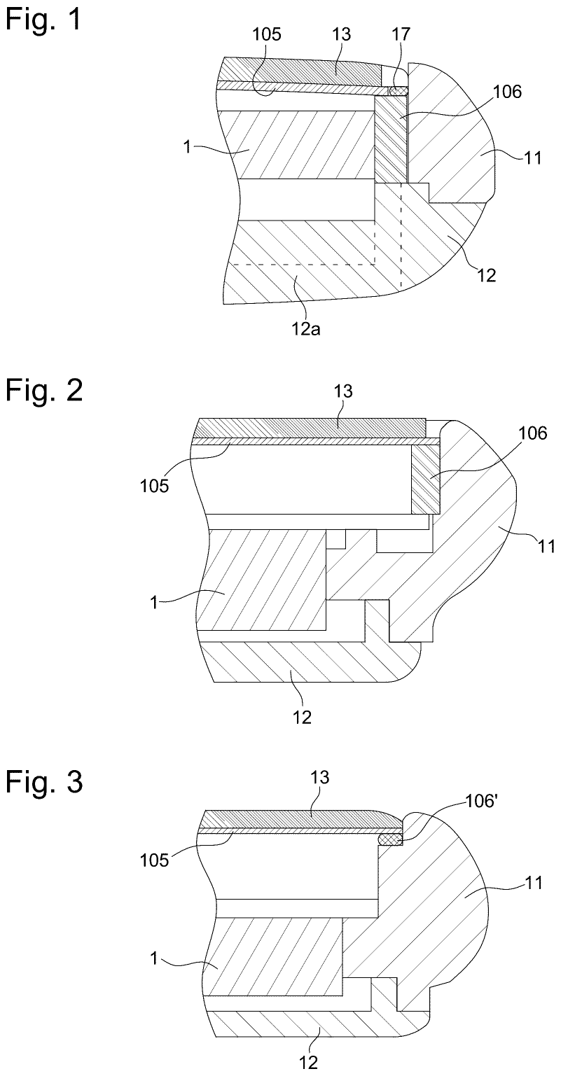

FIG. 1 diagrammatically shows a partial cross-sectional view of a first example embodiment of a timepiece 10 comprising an anti-fogging device 100 according to the invention.

The timepiece 10, such as a wristwatch, is intended to be worn in contact with the wearer's skin, for example on the wrist.

The timepiece 10 comprises a middle 11, intended to receive a horological movement 1.

The horological movement 1 can be a mechanical, electromechanical or electronic movement. Preferably, the horological movement 1 is a mechanical movement.

The middle 11 is closed at the bottom by a back cover 12 and at the top by a protective glass 13, so as to protect the horological movement 1.

The timepiece 10 further comprises a flexible or articulated bracelet (not shown), two ends of which are intended to be coupled, for example removably, to the middle 11, via an ad hoc fastening system which will not be described in this application, allowing the user to wear the timepiece 10, for example on the wrist, and allowing the outer surface of the back cover 12 to be in contact with the wearer's skin.

The back cover 12 has at least one part 12a made from a thermally conductive material, for example a metal-and/or ceramic-and/or carbon fibre-filled polymer-based material. This part 12a is arranged to be in contact with the wearer's skin.

Preferably, the back cover 12 is made entirely of a thermally conductive material, preferably a metal-and/or ceramic-and/or carbon fibre-filled polymer-based material.

Typically speaking, in the present application, a thermally conductive material is considered to have a thermal conductivity greater than or equal to 1 W/m·K (Watt/metre·Kelvin).

Preferably, the back cover 12, or at least the part 12a of the back cover 12, is made from a thermally conductive material with a thermal conductivity greater than 10 W/m·K.

The timepiece 10 further comprises an anti-fogging device 100 for said protective glass 13 to prevent the formation of fog on the inner surface of the protective glass 13, i.e. the surface facing the horological movement 1, or to limit/reduce the presence of visible fog following a major thermal shock.

To this end, the anti-fogging device 100 comprises a layer 105 of transparent conductive oxides (TCO) provided directly on at least a portion of the inner surface of the protective glass 13.

Advantageously, the layer 105 of transparent conductive oxides is provided over the entire inner surface of the protective glass 13.

If the layer 105 of transparent conductive oxides is provided on a portion of the inner surface of the protective glass 13, this must be sufficiently extensive to ensure that the protective glass 13 is brought up to temperature and to prevent fogging.

This layer 105 of transparent conductive oxides has thermal and conductive properties which are used in the anti-fogging device 100 according to the invention.

Preferably, the layer of transparent conductive oxides is deposited on the protective glass 13 by a chemical vapour deposition (CVD) method or by a physical vapour deposition (PVD) method. However, other thin film deposition methods known to a person skilled in the art are also possible.

The layer 105 of transparent conductive oxides is composed, for example, of tin-doped indium oxide, aluminium-doped zinc oxide, zinc oxide or fluorine-doped tin dioxide.

The anti-fogging device 100 further comprises a thermal interface member 106 provided in the middle 11 and configured to bring the layer 105 of transparent conductive oxides into thermal contact by conduction with the back cover 12, or at least with the thermally conductive part 12a of the back cover 12, if the latter is not made entirely of thermally conductive material.

Alternatively, as shown in FIG. 2, the thermal interface member 106 can be configured to bring the layer 105 of transparent conductive oxides into thermal contact by conduction with the middle 11, if the latter is made of a thermally conductive material, the middle 11 then providing heat exchange with the back cover 12, or with the thermally conductive part 12a of the back cover 12.

As required, the thermal interface member 106 can be made of a material that promotes heat exchange by conduction while being electrically insulating.

The thermal interface member 106 is, for example, a thermally conductive pad with a thermal conductivity greater than or equal to 1 W/m·K, preferably greater than 2 W/m·K.

The thermal interface member 106 is arranged in a recess in the middle 11, for example via a positioning system.

Such a positioning system can, for example, comprise a thermally insulating element, or be made entirely of a thermally insulating material, so as to promote thermal conduction between the back cover 12 and the layer 105 of transparent conductive oxides, while thermally insulating the thermal interface member 106 from the middle 11 to prevent heat loss by conduction with the middle 11 in contact with the external environment.

The thermal interface member 106 is for example a thermally conductive pad composed of one or more polymers, for example elastomer, and metallic, ceramic, or carbon-based particles and/or carbon fibres, or a mixture of these particles and/or fibres.

The thermal interface member 106 is, for example, a thermally conductive pad composed of silicone and metallic and/or ceramic particles.

The thermal interface member 106 is, for example, a thermally conductive pad that is annular in shape so as to be in contact with the layer 105 of transparent conductive oxides at a peripheral edge of the protective glass 13 and the back cover 12.

The thermal interface member 106 can be formed by a plurality of thermally conductive pads distributed inside the middle 11, to create a plurality of points of thermal conduction between the back cover 12, the part 12a of the back cover 12, or the middle 11, and the layer 105 of transparent conductive oxides.

As illustrated in FIG. 1, a sealing joint 17 can be provided between the protective glass 13 and the middle 11 to ensure that the timepiece 10 is watertight.

The anti-fogging device 100 according to the invention results in the passive heating, by conduction, of the protective glass 13 by making use of the wearer's body heat when the timepiece 10 is being worn.

The back cover 12, which is thermally conductive and in contact with the wearer's skin, allows heat exchange by “direct” conduction with the thermal interface member 106 when the latter is in contact with the back cover 12, or heat exchange by “indirect” conduction with the thermal interface member 106, via the middle 11 made of a thermally conductive material, when the thermal interface member 106 is in contact only with the middle 11.

The thermal interface member 106 also ensures heat exchange by conduction with the layer 105 of transparent conductive oxides in order to eliminate the cold spot that can exist at the protective glass 13.

Thanks to the invention, the cold spot is no longer located on the protective glass 13. As a result, fog, if it is to form, will form elsewhere in a cold zone not visible to the wearer, for example under the dial.

FIG. 3 illustrates a second example embodiment of the invention.

In this second example embodiment, the thermal interface member 106′ is a thermally conductive elastomer joint positioned between the protective glass 13 and the middle 11, which must be made of a thermally conductive material or comprise a thermally conductive inner part in this second example embodiment so as to be able to exchange heat with the back cover 12 or the thermally conductive part 12a of the back cover 12.

In this second example embodiment, the thermal interface member 106′ also provides a watertight seal between the protective glass 13 and the middle 11.

The thermally conductive elastomer joint forming the thermal interface member 106′ is, for example, a silicone-or fluorosilicone-based elastomer.

The thermally conductive elastomer joint forming the thermal interface member 106′ is, for example, filled with a metallic material (for example aluminium), with carbon (for example graphite), with a ceramic material, or with a mixture of these materials.

1. A timepiece comprising a middle closed by a back cover and by a protective glass, wherein the timepiece comprises an anti-fogging device for said protective glass, said anti-fogging device comprising:
a layer of transparent conductive oxides provided at least on a portion of an internal surface of the protective glass;
a thermal interface member, having a thermal conductivity greater than or equal to 1 W/m·K, provided in said middle and configured to:
a) ensure heat exchange by contact between said conductive oxide layer and the middle, the middle and said back cover being made of a thermally conductive material, or
b) ensure heat exchange by contact between said conductive oxide layer and the back cover, said back cover comprising at least one part made of a thermally conductive material in contact with said thermal interface member.

2. The timepiece according to claim 1, wherein the layer of transparent conductive oxides is composed of tin-doped indium oxide, aluminium-doped zinc oxide, zinc oxide or fluorine-doped tin dioxide.

3. The timepiece according to claim 1, wherein the thermally conductive member is a thermally conductive elastomer joint provided between the middle and the protective glass.

4. The timepiece according to claim 3, wherein the thermally conductive elastomer joint is made of a silicone-or fluorosilicone-based elastomer.

5. The timepiece according to claim 4, wherein the thermally conductive elastomer joint seals the middle at the protective glass.

6. The timepiece according to claim 1, wherein the thermal interface member is a thermally conductive pad housed in a recess in the middle.

7. The timepiece according to claim 6, wherein the thermally conductive pad is composed of a polymer base and metallic, ceramic, or carbon-based particles and/or carbon fibres, or of a mixture of these particles and/or these fibres.

8. The timepiece according to claim 7, wherein the thermally conductive pad is composed of an elastomer base, and is silicone-based, and of ceramic particles.

9. The timepiece according to claim 6, wherein the thermal interface member is formed by a plurality of conductive pads.

10. The timepiece according to claim 6, wherein the thermal interface member has an annular shape.

11. The timepiece according to claim 1, wherein the timepiece comprises a system for positioning the thermal interface member configured to ensure thermal conduction between the back cover and the conductive oxide layer while thermally insulating the thermal interface member from the middle.
